(19) United States
(12) Patent Application Publication
(10) Pub. No.: US 2008/0206924 A1
(43) Pub. Date: Aug. 28, 2008

(54) METHOD FOR FABTRICATING SEMICONDUCTOR DEVICE

(76) Inventor: Kazuhide ABE, Tokyo (JP)

Correspondence Address: RABIN & Berdo, PC, 1101 14TH STREET, NW, SUITE 500, WASHINGTON, DC, 20005, US

(21) Appl. No.: 11/963,485

(22) Filed: Dec. 21, 2007

(30) Foreign Application Priority Data
Feb. 23, 2007 (JP) 2007-043159

(51) Int. Cl. H01L 21/20

(52) U.S. Cl. 438/105; 257/E21.09

(57) ABSTRACT

According to the first aspect of the present invention, a method for fabricating a semiconductor device with a silicon carbide (SiC) film is comprised of a process to grow a silicon carbide film on a substrate; and a process to form a groove in the periphery of a region on the silicon carbide film in which crystal defects are aggregated.

According to the second aspect of the present invention, a method for fabricating a semiconductor device with a silicon carbide (SiC) film is comprised of a process to grow a silicon carbide film on a substrate; and a process to form a groove on said silicon carbide film so that a region in which crystal defects are aggregated in said silicon carbide film is removed.

### CROSS REFERENCE TO RELATED APPLICATION

This application claims the priority of Application No. 2007-043159, filed Feb. 23, 2007 in Japan, the subject matter of which is incorporated herein by reference.

### TECHNICAL FIELD OF THE INVENTION

The present invention relates to a method for fabricating a semiconductor device having a silicon carbide (SiC) film.

### BACKGROUND OF THE INVENTION

A power device using Si prevails in the power electronics field such as motor control of automobiles and electric trains but its insulation resistance is approaching the performance limit. Thus, a material with a wider gap than Si and a larger insulation breakdown electric field is in demand. Formed silicon carbide (SiC), GaN, and diamond have a larger band gap and insulation breakdown electric field than Si. Moreover, these materials have advantages of high-temperature stability and a large saturated drift velocity.

When physical characteristics of SiC are compared with those of Si, the band gap is larger by approximately twice to three times, the insulation breakdown electric field is approximately one digit larger, and the saturated drive velocity is also several times larger. Moreover, since SiC can form SiO2 by thermal oxidation as compared with other wide-gap semiconductors, SiC is excellent in consistency with Si series process. Since p-, n-conductive type control by impurity doping is also possible with SiC, it is advantageous in practical application.

For epitaxial growth of a SiC single-crystal, chemical vapor deposition (CVD) or sublimation method is used. The CVD growth process is carried out in a hot-wall CVD furnace at a temperature of 1500° C. or above using SiH₄, C₃H₈, and H₂. In the sublimation method, SiC powder sealed in a crucible is heated close to 2000° C. so that SiC is grown on a substrate. The sublimation method has an advantage of a larger growth rate over the CVD method.

The SiC epitaxial film can be formed in various methods, but defect reduction with required device performance is insufficient. A crystal defect represented in dislocation causes device characteristic degradation including withstand pressure. Thus, various improvements are made as disclosed in Japanese Patent Laid-Open No. 2004-336079 and Japanese Patent Laid-Open No. 2005-350278.

In a process of forming a SiC device, high heat processing approximately at 1200 to 1800° C. is necessary for activation of dopant or the like. It is concerned that the defect may spread to a high-quality region with fewer defects by re-crystallization, and thus, there is a possibility of lowering the device yield.

### OBJECTS OF THE INVENTION

The present invention was made in view of the above circumstances and is intended to provide a method for fabricating a SiC semiconductor device that can maintain a high-quality device forming region even after a SiC device forming process.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to the first aspect of the present invention, a method for fabricating a semiconductor device with a silicon carbide (SiC) film comprised of: a process to grow a silicon carbide film on a substrate; and a process to form a groove in the periphery of a region on the silicon carbide film in which crystal defects are aggregated.

According to the second aspect of the present invention, a method for fabricating a semiconductor device with a silicon carbide (SiC) film comprised of a process to grow a silicon carbide film on a substrate; and a process to form a groove on the silicon carbide film so that a region in which crystal defects are aggregated in the silicon carbide film is removed.

Here, the region in which the crystal defects are aggregated can be a region having defects of 10⁴ pieces/cm² or more.

The region where the crystal defects are aggregated can be formed intentionally by a predetermined method. In a silicon carbide single-crystal, crystal defects such as dislocation can be aggregated by adjusting a growth surface. These crystal defects can be further aggregated during growth. Thus, locations other than the aggregation region are high-quality regions with fewer crystal defects such as dislocation.

In the present invention as above, since a groove is formed in the periphery of the region where the crystal defects are aggregated, the region where the crystal defects are aggregated and the high-quality regions with fewer defects are spatially separated. Alternatively, the groove is formed on the silicon carbide film so that the region where the crystal defects are aggregated on the silicon carbide film is removed. Therefore, even if high heat treatment such as dopant activation is given, defect expansion (propagation) by influence of the region where the crystal defects are aggregated at recrystallization of a SiC layer can be restricted.

### BRIEF DESCRIPTION OF THE DRAWINGS

FIG. 1 is a plan view illustrating a part of a wafer used in a method for fabricating a semiconductor device according to the present invention.

FIGS. 2A to 2J are sectional views illustrating a fabricating process of the semiconductor device according to the first embodiment of the present invention.

FIGS. 3A to 3I are sectional views illustrating a fabricating process of the semiconductor device according to the second embodiment of the present invention.

### DESCRIPTION OF REFERENCE NUMERALS

101,201 SiC substrate
102,202 SiC layer (epitaxial growth film)
108,208 Oxidized film
103,203 Crystal defect aggregated region
107 Groove
207 Groove

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

First, the first embodiment of the present invention will be described. Here, a part of a method for fabricating DiMOS provided with an epitaxial-grown SiC film on a silicon carbide (SiC) substrate, on which a groove is formed at a position proximate to a region where non-DiMOSFET (Double-Implanted MOSFET) is formed, will be described.

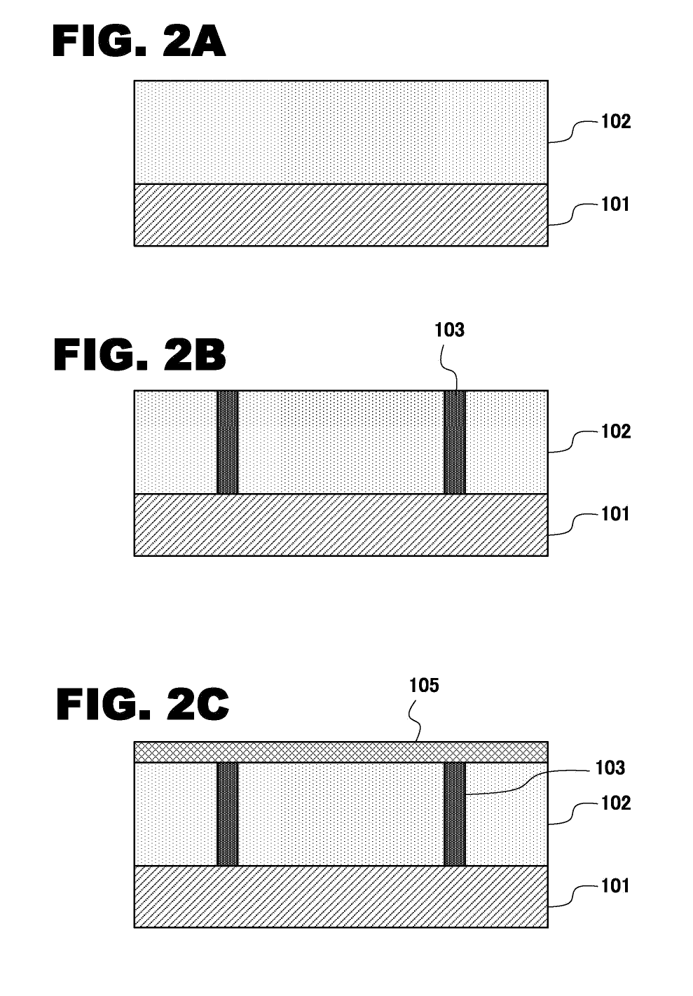

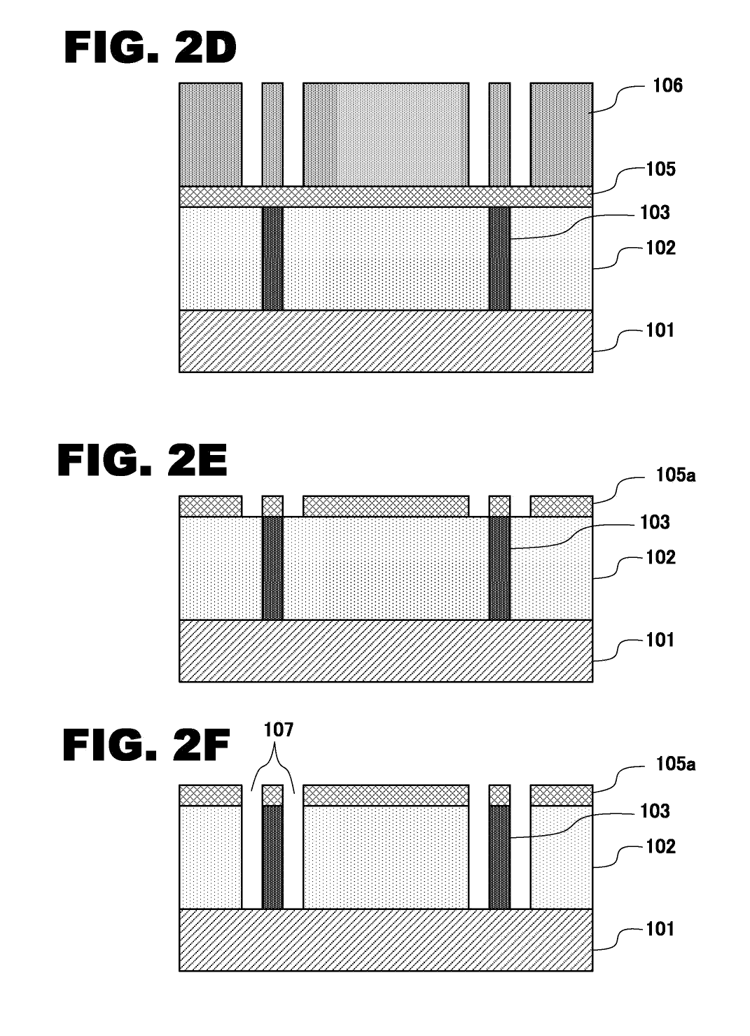

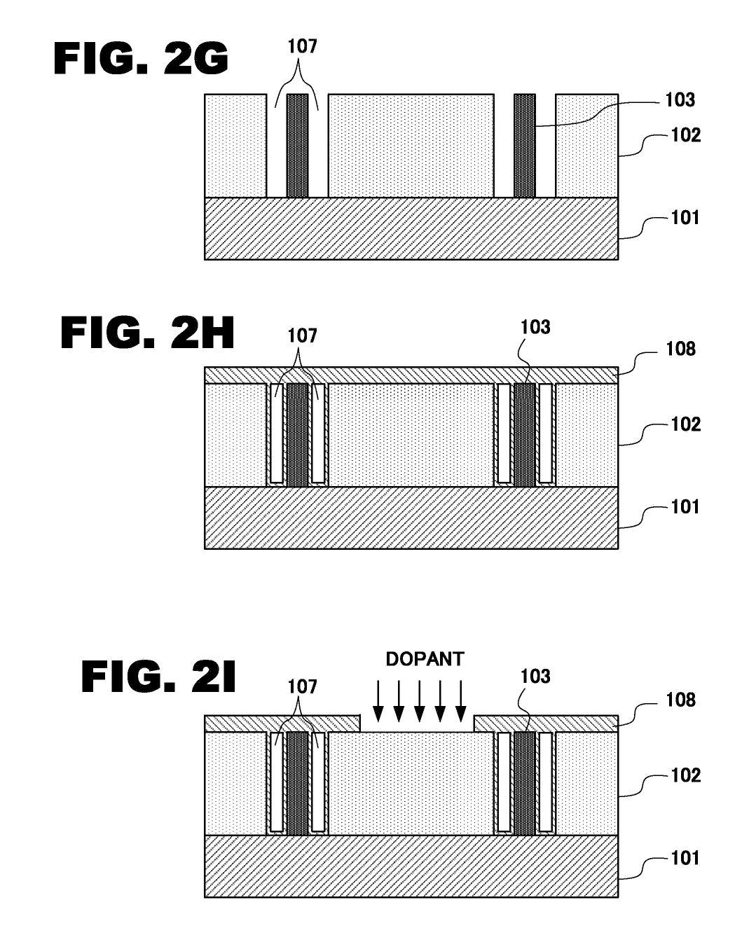

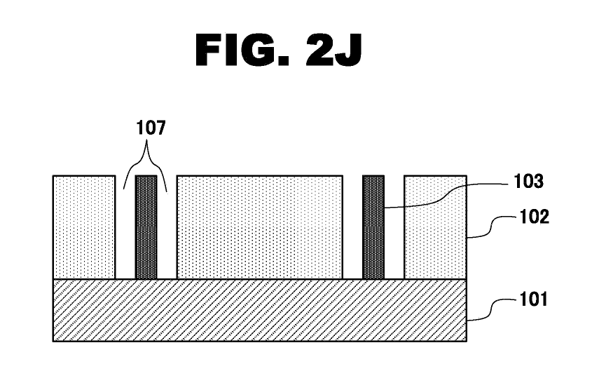

First, in a process shown in FIG. 2A, a SiC substrate 101 on which a silicon carbide (SiC) layer 102 is formed is prepared. The SiC layer 102 is epitaxial-grown on the SiC substrate 101 and set to have a thickness of 15 μm, for example. The epitaxial layer surface is etched back by chemical mechanical polishing (CMP) or the like so that a flat surface is formed.

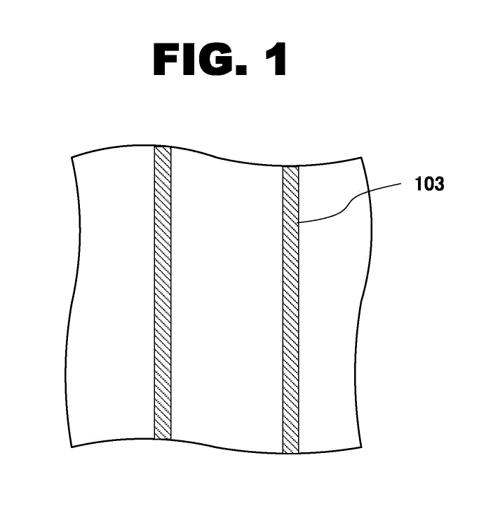

Here, crystal defects such as micropipe, screw dislocation, and edge dislocation are formed in the SiC layer 102. A region where these crystal defects are aggregated is indicated by reference numeral 103 (FIGS. 1 and 2B). The region 103 where the crystal defects are aggregated can be intentionally formed by a predetermined method. The silicon carbide single-crystal can aggregate crystal defects such as dislocation by adjustment of a growth surface. These crystal defects can be further aggregated during growth. Therefore, the locations other than the aggregation region are regions with fewer crystal defects such as dislocation. Local observation of the region 103 where the crystal defects are aggregated is shown in FIG. 1.

Next, in a process shown in FIG. 2C, an oxidized film 105 with a thickness of 2 μm to be a groove-forming mask is formed on the surface of the SiC layer 102. After that, through a photolithography process, patterning of a resist 106 is carried out as shown in FIG. 2D. In formation of the oxidized film 105, chemical vapor deposition (CVD) is carried out under a pressure-reduced atmosphere using a Si (OC₂H₅) gas with setting of a furnace temperature at 700° C. The region 103 may not be only one but may densely exist in plural. In that case, an opening portion is formed at a position proximate to the outermost location of the plural regions 103. The width of the region 103 may be approximately 100 μm.

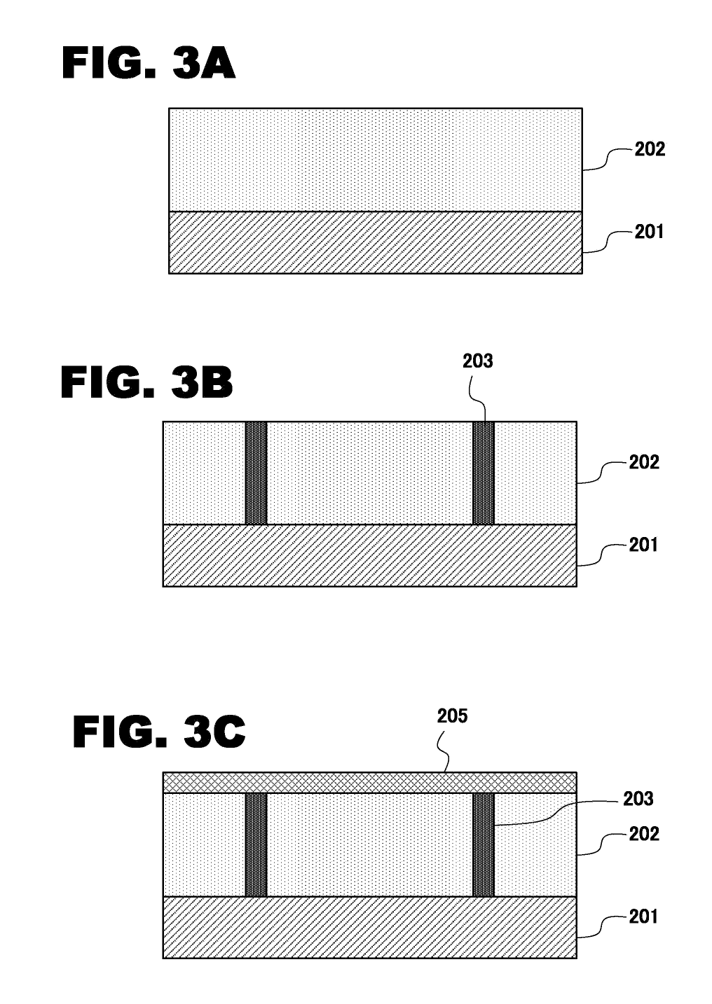

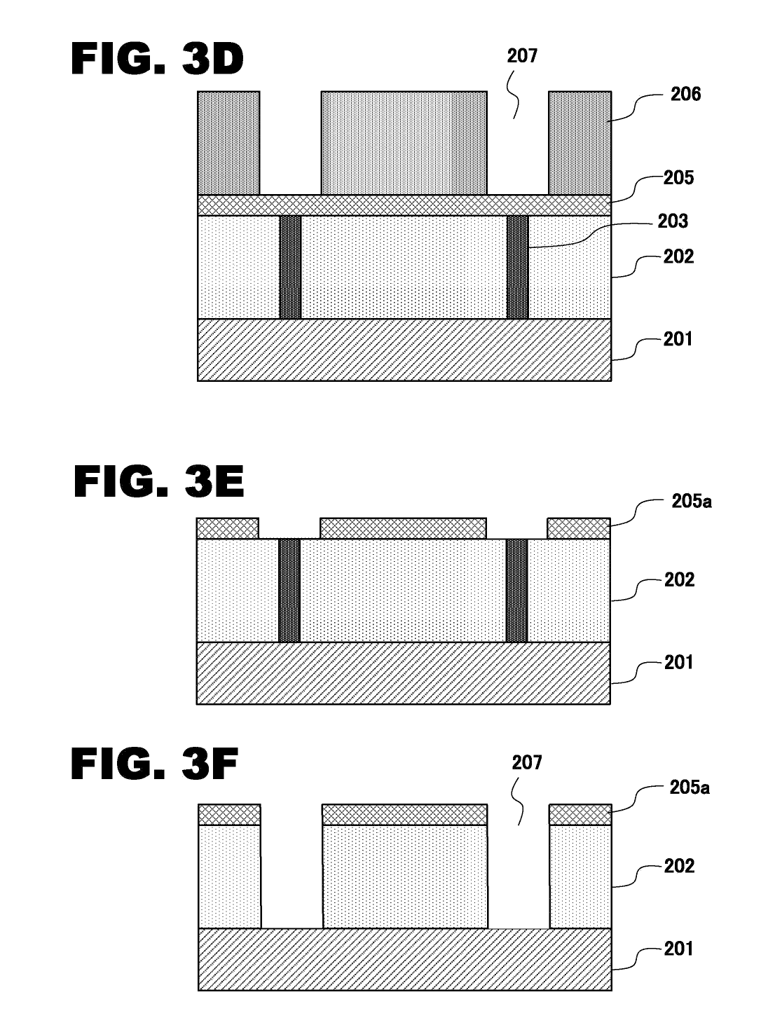

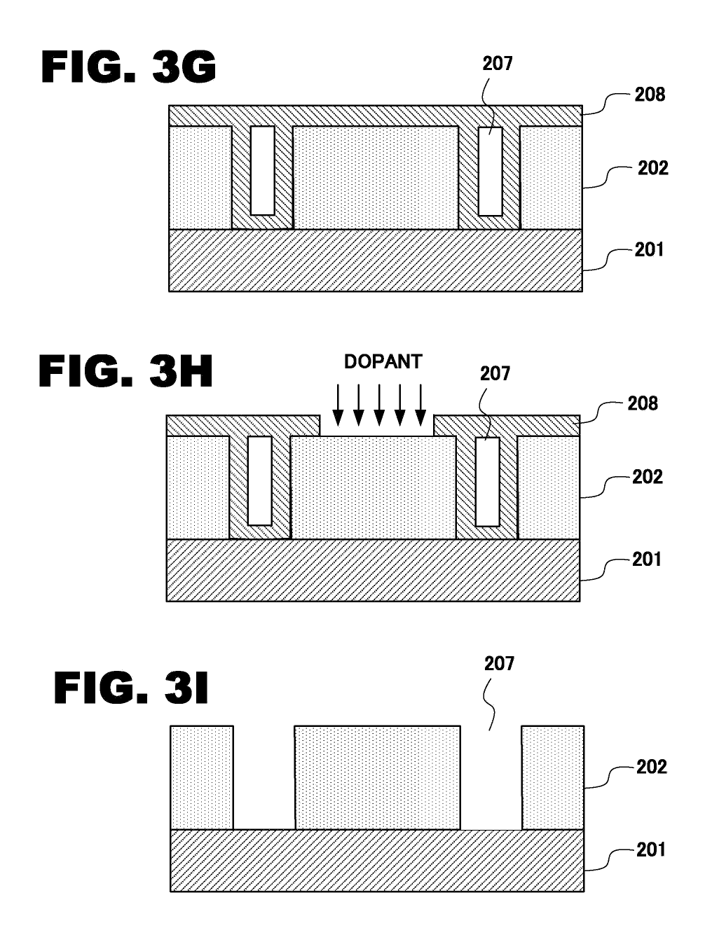

Next, in order to form a groove with the oxidized film 105 as a mask, plasma etching using CHF₃, CF₄, Ar is carried out using the resist mask 106 so as to form an oxidized film mask 105a (FIG. 3E).

Subsequently, the wafer is fed to another etching device, and plasma etching using SF₆ is carried out using the oxidized film mask 105a. And a groove 107 with a width of approximately 2 μm and a depth of approximately 15 μm, for example, is formed in the SiC layer 102, which is a non-DiMOS formed region (FIG. 2F). By the above operation, the region 103 where crystal defects are aggregated and the high-quality region with fewer defects are separated by the groove 107.

After that, by resist removal by ashing and HF removal of the oxidized film mask 105a, a structure shown in FIG. 2G is formed.

Next, in a process shown in FIG. 2H, on the SiC layer formed substrate on which the groove 107 is formed, an oxidized film 108 with a thickness of 2 μm to be a mask for dopant implantation is formed. The method for forming the oxidized film 108 and the conditions are the same as those for the oxidized film 105.

Next, by a known photolithography and dry etching, the oxidized film 108 in a predetermined region for dopant implantation is opened (FIG. 2I). Then, nitrogen (N), phosphorous (P) in the case of the n-type dopant or aluminum (Al) or boron (B) in the case of p-type dopant is implanted in a multistage manner of plural times by energy of several tens of kV to several MV (FIG. 2I).

After implantation of impurity is finished, as shown in FIG. 2J, by HF removal of the mask 108 for dopant implantation and by repeating the process from mask formation to mask removal, a well region or a source region is formed. Activation heat treatment after dopant implantation is executed for each dopant or in a lump sum after all the implantations are finished. Treatment conditions are set at 1 to 30 seconds at a temperature of 1200 to 1800° C. in an Ar atmosphere. By this treatment, electric activation of the dopant and recovery from damage in the implanted layer are realized.

Next, the second embodiment of the present invention will be described. In this embodiment, on a silicon carbide (SiC) substrate provided with an epitaxial-growth SiC film, a region where crystal defects are aggregated located in a non-DiMOS (double-Implanted MOSFET) formed region is removed by dry etching.

First, in a process shown in FIG. 3A, a SiC substrate 201 on which a silicon carbide (SiC) layer 202 is formed is prepared. The SiC layer 202 is epitaxial-grown on the SiC substrate 201 and set to have a thickness of 15 μm, for example. The surface of the epitaxial layer 202 is etched back by chemical mechanical polishing (CMP) or the like so that a flat surface is formed.

Here, crystal defects such as micropipe, screw dislocation, and edge dislocation are formed in the SiC layer 202. A region where these crystal defects are aggregated is indicated by reference numeral 203 (FIGS. 1 and 3B). The region 203 where the crystal defects are aggregated can be intentionally formed by a predetermined method. The silicon carbide single-crystal can aggregate crystal defects such as dislocation by adjustment of a growth surface. These crystal defects can be further aggregated during growth. Therefore, the locations other than the aggregation region are high-quality regions with fewer crystal defects such as dislocation. Local observation of the region 203 where the crystal defects are aggregated is shown in FIG. 1.

Next, as shown in FIG. 3C, an oxidized film 205 with a thickness of 2 μm to be a mask for groove forming is formed on the surface of the SiC layer 202 formed on the SiC substrate 201. In formation of the oxidized film 205, chemical vapor deposition (CVD) is carried out under a pressure-reduced atmosphere using a Si (OC₂H₅) gas with setting of a furnace temperature at 700° C.

Next, as shown in FIG. 3D, patterning of a resist 206 is carried out through a photolithography process. At this time, the opening portion by patterning should include the region 203 where crystal defects are aggregated. The width of the region 203 where the crystal defects are aggregated is approximately 10 μm. Next, in a process shown in FIG. 3E, an oxidized film mask 205a is formed by plasma etching using CHF₃, CF₄, Ar using the resist mask 206.

After that, the wafer is fed to another etching device, and plasma etching using SF₆ is carried out using the oxidized film mask 205a, and as shown in FIG. 3F, a groove 207 with a width of approximately 12 μm and a depth of approximately 15 μm, for example, is formed in the SiC layer 202, which is a non-DiMOS formed region. By the above operation, only the high-quality region with fewer defects such as micropipe, screw dislocation, and edge dislocation are separated by the groove 107. Subsequently, resist removal by ashing and HF removal of the oxidized film mask 205a are executed.

Next, in a process shown in FIG. 3G, on the SiC layer formed substrate on which the groove 207 is formed, an oxidized film 208 with a thickness of 2 μm to be a mask for dopant implantation is formed. The method for forming the oxidized film 208 and the conditions are the same as those for the oxidized film 205.

Next, by a known photolithography and dry etching, the oxidized film in a predetermined region for dopant implantation is opened (FIG. 3H). Then, nitrogen (N), phosphorous (P) in the case of the n-type dopant or aluminum (Al) or boron (B) in the case of p-type dopant is implanted in a multistage manner of plural times by energy of several tens of kV to several MV (FIG. 3H).

After implantation of impurity is finished, as shown in FIG. 3I, by HF removal of the mask 208 for dopant implantation and by repeating the process from mask formation to mask removal, a well or a source is formed. Activation heat treatment after dopant implantation is executed for each dopant or in a lump sum after all the implantations are finished. Treatment conditions are set at 11 to 30 seconds at a temperature of 1200 to 1800° C. in an Ar atmosphere. By this treatment, electric activation of the dopant and recovery from damage in the implanted layer are realized.

What is claimed is:

1. A method for fabricating a semiconductor device with a silicon carbide (SiC) film comprising:
a process to grow a silicon carbide film on a substrate; and
a process to form a groove in the periphery of a region of said silicon carbide film in which crystal defects are aggregated.

2. The method for fabricating a semiconductor device according to claim 1, wherein
said region in which the crystal defects are aggregated is a region with defects of 10⁴ pieces/cm² or more.

3. The method for fabricating a semiconductor device according to claim 1, wherein
said region where the crystal defects are aggregated is formed intentionally by a predetermined method.

4. The method for fabricating a semiconductor device according to claim 1, wherein
said crystal defects include at least one of micropipe, screw dislocation, or edge dislocation.

5. A method for fabricating a semiconductor device having a silicon carbide (SiC) film comprising:
a process to grow a silicon carbide film on a substrate; and
a process to grow a groove on said silicon carbide film so that a region in which crystal defects are aggregated in said silicon carbide film is removed.

6. The method for fabricating a semiconductor device according to claim 5, wherein
said region in which the crystal defects are aggregated is a region having defects of 10⁴ pieces/cm² or more.

7. The method for fabricating a semiconductor device according to claim 5, wherein
said region where the crystal defects are aggregated is formed intentionally by a predetermined method.

8. The method for fabricating a semiconductor device according to claim 5, wherein
said crystal defects include at least one of micropipe, screw dislocation, and edge dislocation.
